(19) United States
(12) Patent Application Publication
(10) Pub. No.: US 2026/0290413 A1
(43) Pub. Date: Sep. 24, 2026

(54) SEMICONDUCTOR DEVICE AND DATA PROCESSING SYSTEM

(71) Applicant: Kioxia Corporation, Tokyo (JP)

(72) Inventors: Takahiro SHIMIZU, Yokohama Kanagawa (JP); Yoshihisa TSUKADA, Kamakura Kanagawa (JP); Naoki KOBAYASHI, Kawasaki Kanagawa (JP); Yuko UTSUNOMIYA, Yokohama Kanagawa (JP); Makoto MIAKASHI, Yokohama Kanagawa (JP); Takaya HANDA, Yokohama Kanagawa (JP)

(21) Appl. No.: 19/319,655

(22) Filed: Sep. 4, 2025

(30) Foreign Application Priority Data
Mar. 18, 2025 (JP) 2025-043608

(51) Int. Cl. G11C 7/04; G06F 3/06

(52) U.S. Cl. CPC G11C 7/04; G06F 3/0679; G11C 2207/2254

(57) ABSTRACT

A semiconductor device includes: an electrode used in data input and output; a pull-up circuit and a pull-down circuit, each configured to control a voltage of the electrode; an internal circuit configured to output data via the electrode and to receive data via the electrode; a control circuit capable of executing an operation of the internal circuit and a calibration operation of adjusting impedances of the pull-up circuit and the pull-down circuit; and a temperature sensor configured to supply temperature data to the control circuit. The control circuit is configured to acquire the temperature data from the temperature sensor during execution of an internal operation, and execute the calibration operation according to the acquired temperature data.

### CROSS-REFERENCE TO RELATED APPLICATION(S)

This application is based upon and claims the benefit of priority from Japanese Patent Application No. 2025-043608, filed Mar. 18, 2025, the entire contents of which are incorporated herein by reference.

### FIELD

Embodiments described herein relate generally to a semiconductor device and a data processing system.

### BACKGROUND

A semiconductor device including electrodes used in data input and output, a pull-up circuit and a pull-down circuit that control a voltage of the electrodes, and an internal circuit that outputs data to be output via the electrodes and receives data input via the electrodes is known.

### BRIEF DESCRIPTION OF THE DRAWINGS

FIG. 1 is a schematic block diagram illustrating a configuration of a memory system according to a first embodiment.

FIG. 2 is a schematic side view illustrating a configuration example of the memory system.

FIG. 3 is a schematic plan view illustrating the configuration example of the memory system.

FIG. 4 is a schematic circuit diagram illustrating a configuration of a portion of a memory die.

FIG. 5 is a schematic perspective view illustrating a configuration of a portion of a memory cell array.

FIG. 6 is a schematic cross-sectional view of the memory cell array, illustrating a read operation.

FIG. 7 is a schematic cross-sectional view of the memory cell array, illustrating a write operation.

FIG. 8 is a schematic cross-sectional view of the memory cell array, illustrating an erase operation.

FIG. 9 is a schematic block diagram illustrating a configuration of a peripheral circuit.

FIG. 10 is a schematic circuit diagram illustrating a configuration of a termination resistance adjusting circuit in an input/output control circuit.

FIG. 11 is a table illustrating impedances of the termination resistance adjusting circuit in the input/output control circuit.

FIGS. 12 and 13 are schematic circuit diagram illustrating a configuration of a calibration circuit.

FIG. 14 is a schematic timing chart illustrating an example of a timing of executing a calibration operation.

FIGS. 15-16 are schematic timing charts illustrating the calibration operation during the write operation.

FIG. 17 is a schematic timing chart illustrating the calibration operation during the read operation.

FIG. 18 is a schematic timing chart illustrating the calibration operation during the erase operation.

FIG. 19 is a schematic timing chart illustrating the calibration operation during a recovery operation.

FIG. 20 is a schematic block diagram illustrating a configuration of a memory system according to a second embodiment.

FIGS. 21-22 are schematic timing charts illustrating the calibration operation during the write operation in the second embodiment.

FIG. 23 is a schematic timing chart illustrating the calibration operation during the read operation in the second embodiment.

### DETAILED DESCRIPTION

Embodiments provide a semiconductor device that operates at high speed.

In general, according to one embodiment, a semiconductor device includes: an electrode used in data input and output; a pull-up circuit and a pull-down circuit, each configured to control a voltage of the electrode; an internal circuit configured to output data via the electrode and to receive data via the electrode; a control circuit capable of executing an operation of the internal circuit and a calibration operation of adjusting impedances of the pull-up circuit and the pull-down circuit; and a temperature sensor configured to supply temperature data to the control circuit. The control circuit is configured to acquire the temperature data from the temperature sensor during execution of an internal operation, and execute the calibration operation according to the acquired temperature data.

Next, the semiconductor device according to the embodiments will be described in detail with reference to the drawings. It should be noted that the following embodiments are merely examples and are not intended to limit the present disclosure.

In the present specification, the term “semiconductor device” may refer to a semiconductor memory device such as a memory die (memory chip), or refer to something other than a semiconductor memory device such as an integrated circuit for calculation or an integrated circuit for communication.

In the present specification, the term “data processing system” may refer to a memory system such as a memory card or SSD including a memory die (memory chip) and a controller (control device), or may refer to a data processing system having other functions.

In the present specification, the term “internal circuit” may refer to a memory cell array, a calculation circuit, a communication circuit, or the like.

In the present specification, when it is said that a first configuration is “electrically connected” to a second configuration, the first configuration may be directly connected to the second configuration, or the first configuration may be connected to the second configuration via a wiring, a semiconductor member, a transistor, or the like. For example, when three transistors are connected in series, the first transistor is “electrically connected” to the third transistor even when the second transistor is in an OFF state.

In the present specification, when it is said that a first configuration is “electrically connected between” a second configuration and a third configuration, this may mean that the first configuration, the second configuration, and the third configuration are connected in series and the second configuration is electrically connected to the third configuration via the first configuration.

In the present specification, when it is said that a circuit or the like “electrically connects” two wirings or the like, this may mean, for example, that the circuit or the like includes a transistor or the like, the transistor or the like is provided in the current path between the two wirings, and the transistor or the like enters an ON state.

### First Embodiment

### Memory System 10

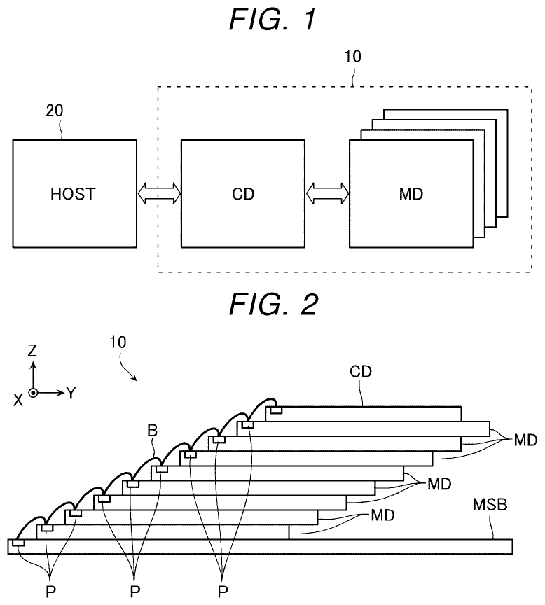

FIG. 1 is a schematic block diagram illustrating a configuration of a memory system 10.

The memory system 10 executes operations such as reading, writing, and erasing of user data in response to signals transmitted from a host computer 20. The memory system 10 is, for example, a memory card, an SSD, or any other system capable of storing user data. The memory system 10 includes a plurality of memory dies MD that store user data, and a controller die CD connected to the plurality of memory dies MD and the host computer 20. The controller die CD includes, for example, a processor, a RAM, or the like, and executes processes such as conversion between logical addresses and physical addresses, bit error detection/correction, garbage collection (also referred to as compaction), and wear leveling.

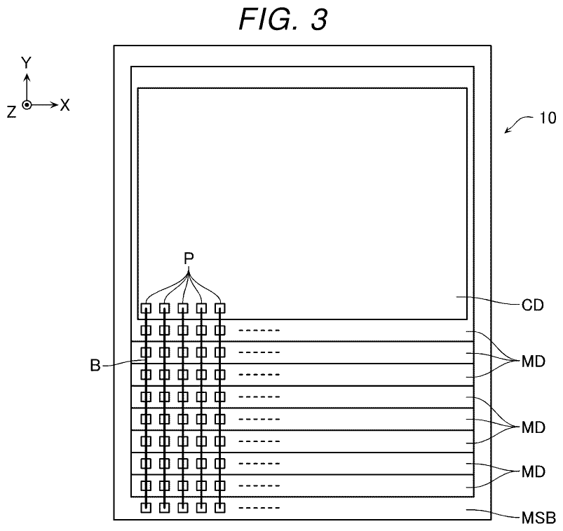

FIG. 2 is a schematic side view illustrating a configuration example of the memory system 10. FIG. 3 is a schematic plan view illustrating the same configuration example. For convenience of explanation, some components are omitted in FIGS. 2 and 3.

As illustrated in FIG. 2, the memory system 10 according to the present embodiment includes a mounting substrate MSB, the plurality of memory dies MD stacked on the mounting substrate MSB, and the controller die CD stacked on the memory dies MD. A pad electrode P is provided at an end region of an upper surface of the mounting substrate MSB in a Y direction, and a portion of other regions is bonded to a lower surface of the memory die MD via an adhesive or the like. The pad electrode P is provided at an end region of an upper surface of the memory dies MD in the Y direction, and other regions are bonded to a lower surface of other memory die MD or the controller die CD via an adhesive or the like. The pad electrode P is provided at an end region of an upper surface of the controller die CD in the Y direction.

As illustrated in FIG. 3, the mounting substrate MSB, the memory dies MD, and the controller die CD each include a plurality of pad electrodes P arranged in the X direction. The plurality of pad electrodes P provided on the mounting substrate MSB, the memory dies MD, and the controller die CD are connected to each other via bonding wires B.

It should be noted that the configuration illustrated in FIGS. 2 and 3 is merely an example, and the specific configuration can be appropriately adjusted. For example, in the example illustrated in FIGS. 2 and 3, the controller die CD is stacked on the plurality of memory dies MD, and the components are connected by the bonding wires B. In such configuration, the plurality of memory dies MD and the controller die CD are provided in one package. However, the controller die CD may be provided in a separate package from the memory die MD. In addition, the plurality of memory dies MD and the controller die CD may be connected to each other via through-electrodes or the like instead of the bonding wires B.

### Configuration of Memory Die MD

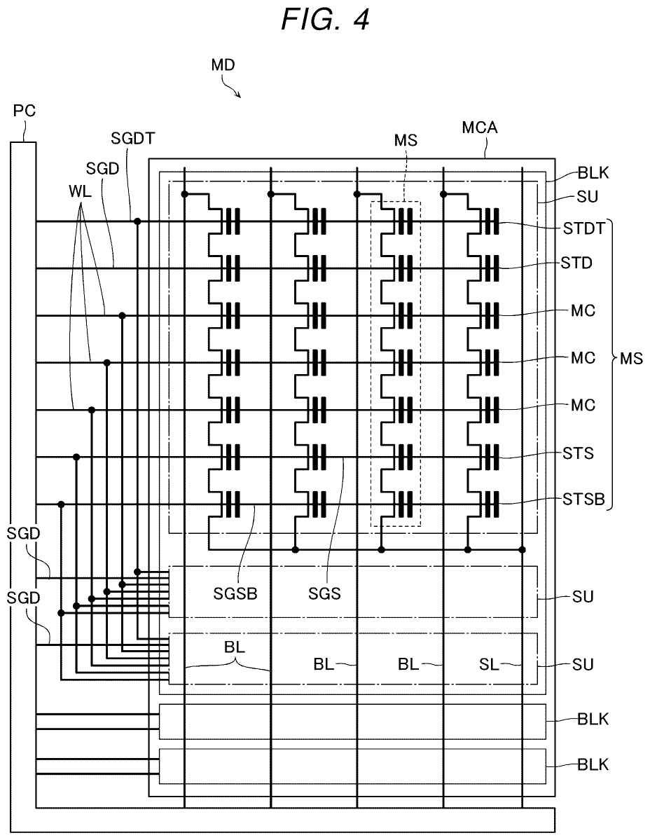

FIG. 4 is a schematic circuit diagram illustrating a configuration of a portion of the memory die MD. As illustrated in FIG. 4, the memory die MD includes a memory cell array MCA that stores user data, and a peripheral circuit PC connected to the memory cell array MCA.

### Configuration of Memory Cell Array MCA

The memory cell array MCA includes a plurality of memory blocks BLK. Each of the memory blocks BLK includes a plurality of string units SU. Each of the plurality of string units SU includes a plurality of memory strings MS. One end of each of the plurality of memory strings MS is connected to the peripheral circuit PC via a bit line BL. The other ends of the plurality of memory strings MS are connected to the peripheral circuit PC via a common source line SL.

The memory string MS includes drain-side select transistors STDT and STD, a plurality of memory cells MC (also referred to as memory cell transistors), and source-side select transistors STS and STSB, that are connected in series between the bit line BL and the source line SL. Hereinafter, the drain-side select transistors STDT and STD and the source-side select transistors STS and STSB may be simply referred to as select transistors STDT, STD, STS, STSB, or the like

The memory cell MC is a field effect transistor including a semiconductor layer, a gate insulating film, and a gate electrode. The semiconductor layer functions as a channel region. The gate insulating film includes a charge storage film. A threshold voltage of the memory cell MC changes depending on an amount of charge in the charge storage film. The memory cell MC stores one or a plurality of bits of user data. A plurality of word lines WL is respectively connected to the gate electrode of each of the plurality of memory cells MC corresponding to one memory string MS. The word lines WL are provided for each of the memory blocks BLK, and each word line WL is commonly connected across all the memory strings MS in the memory block BLK.

The select transistors STDT, STD, STS, and STSB are field effect transistors each including a semiconductor layer, a gate insulating film, and a gate electrode. The semiconductor layer functions as a channel region. Select gate lines SGDT, SGD, SGS, and SGSB are respectively connected to the gate electrode of each of the select transistors STDT, STD, STS, and STSB. The drain-side select gate line SGD is provided separately for each string unit SU, and is commonly connected to all the memory strings MS in the string unit SU. The drain-side select gate line SGDT and the source-side select gate lines SGS and SGSB are provided for the memory block BLK, and are commonly connected to all the memory strings MS in the memory block BLK.

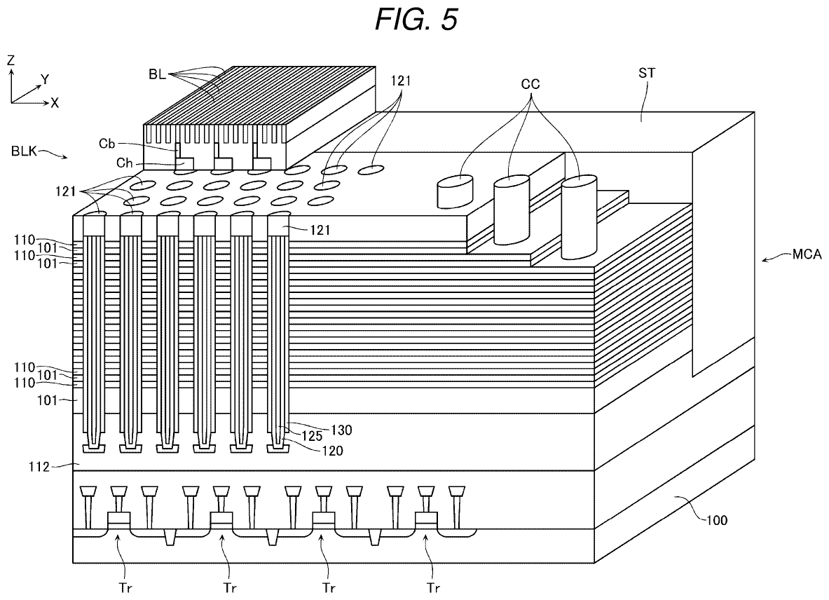

FIG. 5 is a schematic perspective view illustrating a configuration of a portion of the memory cell array MCA. The memory cell array MCA is provided above a semiconductor substrate 100. A plurality of transistors Tr that make up the peripheral circuit PC are provided on an upper surface of the semiconductor substrate 100. Each of the plurality of transistors Tr includes a channel region including a portion of the upper surface of the semiconductor substrate 100, a gate insulating film formed on the upper surface of the semiconductor substrate 100, and a gate electrode facing the channel region with the gate insulating film interposed therebetween.

The memory cell array MCA includes a plurality of memory blocks BLK arranged in the Y direction. An inter-block insulating layer ST made of silicon oxide (SiO₂) or the like is provided between two memory blocks BLK adjacent to each other in the Y direction. A plurality of bit lines BL arranged in the X direction and extending in the Y direction are provided above the memory cell array MCA.

The memory block BLK includes a plurality of conductive layers 110 arranged in the Z direction, a plurality of semiconductor pillars 120 extending in the Z direction, and a plurality of gate insulating films 130 each provided between the plurality of conductive layers 110 and the plurality of semiconductor pillars 120.

The conductive layer 110 is a conductive layer extending in the X direction and having a substantially plate-like shape. The conductive layer 110 may include a stacked film or the like of a barrier conductive film such as titanium nitride (TiN) and a metal film such as tungsten (W). The conductive layer 110 may also include polycrystalline silicon or the like containing impurities such as phosphorus (P) or boron (B). An insulating layer 101 such as silicon oxide (SiO₂) is provided between the plurality of conductive layers 110 arranged in the Z direction.

One or a plurality of conductive layers 110 located in the lowest layer among the plurality of conductive layers 110 function as the source-side select gate line SGSB (FIG. 4) and the gate electrode of the plurality of source-side select transistors STSB connected thereto (FIG. 4).

One or a plurality of conductive layers 110 located above the lowest layer function as the source-side select gate line SGS (FIG. 4) and the gate electrode of the plurality of source-side select transistors STS connected thereto (FIG. 4).

A plurality of conductive layers 110 positioned further above function as the word lines WL (FIG. 4) and the gate electrode of the plurality of memory cells MC connected thereto (FIG. 4).

One or a plurality of conductive layers 110 located further above function as the drain-side select gate line SGD (FIG. 4) and the gate electrode of the plurality of drain-side select transistors STD connected thereto (FIG. 4).

One or a plurality of conductive layers 110 located further above function as the drain-side select gate line SGDT (FIG. 4) and the gate electrode of the plurality of drain-side select transistors STDT connected thereto (FIG. 4).

A semiconductor layer 112 is provided below the plurality of conductive layers 110. The semiconductor layer 112 may include, for example, polycrystalline silicon or the like containing N-type impurities such as phosphorus (P). The insulating layer 101 such as silicon oxide (SiO₂) is provided between the semiconductor layer 112 and the conductive layer 110.

The semiconductor layer 112 functions as the source line SL (FIG. 4). The source line SL is provided in common to all the memory blocks BLK in the memory cell array MCA, for example.

The semiconductor pillars 120 are arranged in a predetermined pattern in the X direction and the Y direction. The semiconductor pillar 120 functions as a channel region of the plurality of memory cells MC and the select transistors STDT, STD, STS, and STSB in one memory string MS (FIG. 4). The semiconductor pillar 120 is, for example, a semiconductor layer such as polycrystalline silicon (Si). The semiconductor pillar 120 has, for example, a substantially cylindrical shape, and an insulating layer 125 such as silicon oxide is provided in a center portion. An outer circumferential surface of the semiconductor pillar 120 is surrounded by the conductive layer 110 and faces the conductive layer 110.

An impurity region 121 containing N-type impurities such as phosphorus (P) is provided at an end on the bit line BL side of the semiconductor pillar 120. The impurity region 121 is connected to the bit line BL via a contact electrode Ch and a contact electrode Cb.

The gate insulating film 130 has a substantially cylindrical shape that covers the outer circumferential surface of the semiconductor pillar 120. The gate insulating film 130 includes, for example, a tunnel insulating film, a charge storage film, and a block insulating film stacked between the semiconductor pillar 120 and the conductive layer 110. The tunnel insulating film and the block insulating film are, for example, insulating films such as silicon oxide (SiO₂). The charge storage film is a film such as silicon nitride (SiN) capable of storing charges. The tunnel insulating film, the charge storage film, and the block insulating film have a substantially cylindrical shape, and extend in the Z direction along the outer circumferential surface of the semiconductor pillar 120 except for a contact portion between the semiconductor pillar 120 and the semiconductor layer 112.

Alternatively, the gate insulating film 130 may include a floating gate including, for example, polycrystalline silicon containing N-type or P-type impurities.

A plurality of contact electrodes CC are connected to the plurality of conductive layers 110. The plurality of conductive layers 110 are electrically connected to the peripheral circuit PC via the plurality of contact electrodes CC. As illustrated in FIG. 5, the plurality of contact electrodes CC extend in the Z direction and lower ends thereof are connected to the conductive layer 110. The contact electrode CC may include, for example, a stacked film or the like of a barrier conductive film such as titanium nitride (TiN) and a metal film such as tungsten (W).

The memory cell array MCA may be formed upside down. For example, the bit lines BL may be provided below the plurality of memory blocks BLK, and the semiconductor layer 112 may be provided above the plurality of conductive layers 110.

### Operation of Memory Cell Array MCA

Next, the operation of the memory cell array MCA will be described. The memory cell array MCA according to the present embodiment is configured to be able to execute a read operation, a write operation, and an erase operation. In the following description, the read operation, the write operation, and the erase operation of the memory cell array MCA may be referred to as “core operation”.

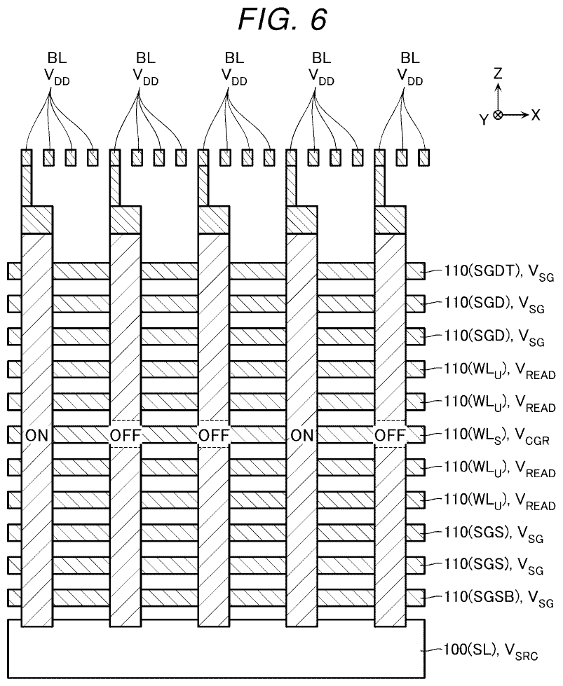

FIG. 6 is a schematic cross-sectional view illustrating the read operation. In the following description, the word line WL as an operation target may be referred to as a selected word line WL_{S}, and the rest of word lines WL may be referred to as non-selected word lines WL_{U}.

In the read operation, for example, an operating voltage V_{DD} is supplied to the bit line BL. A voltage V_{SRC} is supplied to the source line SL. The voltage V_{SRC} may be greater than a ground voltage V_{SS} or may be equal to the ground voltage V_{SS}. The operating voltage V_{DD} is greater than the voltage V_{SRC}.

In the read operation, a voltage V_{SG} is supplied to the drain-side select gate lines SGDT and SGD. The voltage V_{SG} is greater than the operating voltage V_{DD}. The voltage difference between the voltage V_{SG} and the operating voltage V_{DD} is greater than threshold voltages of the drain-side select transistors STDT and STD. Therefore, an electron channel is formed in the channel regions of the drain-side select transistors STDT and STD, and the operating voltage V_{DD} is transferred.

In the read operation, the voltage V_{SG} is supplied to the source-side select gate lines SGS and SGSB. The voltage V_{SG} is greater than the voltage V_{SRC}. The voltage difference between the voltages V_{SG} and V_{SRC} is greater than threshold voltages of the source-side select transistors STS and STSB. Therefore, an electron channel is formed in the channel regions of the source-side select transistors STS and STSB, and the voltage V_{SRC} is transferred.

In the read operation, a read pass voltage V_{READ} is supplied to the non-selected word lines WL_{U}. The read pass voltage V_{READ} is greater than the operating voltage V_{DD} and the voltage V_{SRC}. A voltage difference between the read pass voltage V_{READ} and the operating voltage V_{DD} and the voltage V_{SRC} is greater than the threshold voltage of the memory cell MC regardless of data stored in the memory cell MC. Therefore, an electron channel is formed in the channel region of the non-selected memory cell MC, and the operating voltage V_{DD} and the voltage V_{SRC} are transferred to the selected memory cell MC.

In the read operation, a read voltage V_{CGR} is supplied to the selected word line WL_{S} The read voltage VCGR is less than the read pass voltage V_{READ}. A voltage difference between the read voltage V_{CGR} and the voltage V_{SRC} may be greater than the threshold voltage of a portion of the memory cells MC storing data. In such a case, a portion of the memory cells MC storing data enters an ON state. Accordingly, a current flows through the bit line BL connected to such memory cells MC. Meanwhile, a voltage difference between the read voltages V_{CGR} and V_{SRC} may be smaller than the threshold voltage of a portion of the memory cells MC storing data. In such a case, a portion of the memory cell MC storing data enters an OFF state. Therefore, no current flows to the bit line BL connected to such memory cells MC.

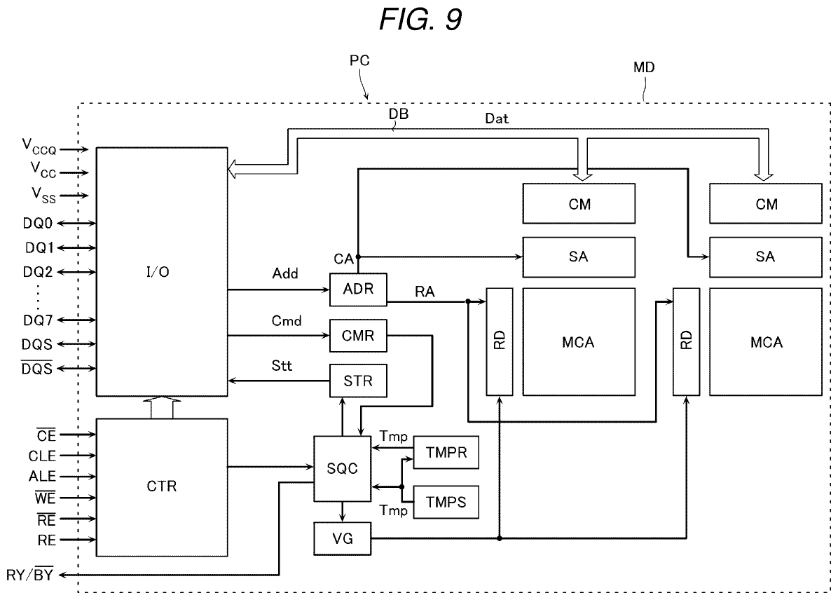

In the read operation, a current or a voltage of each bit line BL is detected by a sense amplifier SA (FIG. 9) described later, stored as user data Dat, and stored in a cache memory CM (FIG. 9) described later.

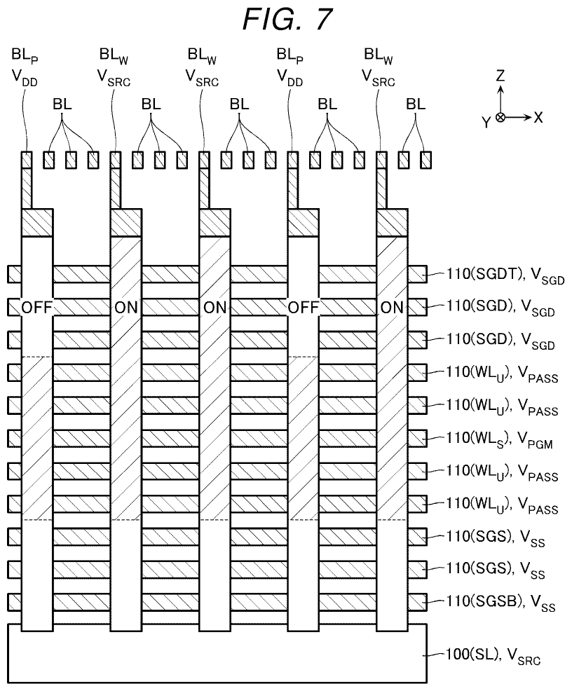

FIG. 7 is a schematic cross-sectional view illustrating the write operation.

In the write operation, for example, the voltage V_{SRC} is supplied to the bit line BL_{W} connected to a memory cell MC for which a threshold voltage is to be adjusted among the plurality of selected memory cells MC. The operating voltage V_{DD} is supplied to a bit line BL_{P} connected to a memory cell MC for which a threshold voltage is not to be adjusted among the plurality of selected memory cells MC. Hereinafter, among the plurality of selected memory cells MC, a memory cell for which a threshold voltage is to be adjusted may be referred to as “write memory cell MC”, and a memory cell for which a threshold voltage is not to be adjusted may be referred to as “inhibited memory cell MC”.

In the write operation, a voltage V_{SGD} is supplied to the drain-side select gate lines SGDT and SGD.

The voltage V_{SGD} is greater than the voltage V_{SRC}. A voltage difference between the voltage V_{SGD} and the voltage V_{SRC} is greater than the threshold voltages of the drain-side select transistors STDT and STD. Therefore, an electron channel is formed in the channel regions of the drain-side select transistors STDT and STD connected to the bit line BL_{W}, and the voltage V_{SRC} is transferred.

Meanwhile, a voltage difference between the voltage V_{SGD} and the operating voltage V_{DD} is smaller than the threshold voltages of the drain-side select transistors STDT and STD. Therefore, the drain-side select transistors STDT and STD connected to the bit line BL_{P} enter an OFF state.

In the write operation, the voltage V_{SRC} is supplied to the source line SL, and the ground voltage V_{SS} is supplied to the source-side select gate lines SGS and SGSB. Thus, the source-side select transistors STS and STSB enter an OFF state.

In the write operation, a write pass voltage V_{PASS} is supplied to the non-selected word lines WL_{U}. The write pass voltage V_{PASS} is greater than the read pass voltage V_{READ}. A voltage difference between the write pass voltage V_{PASS} and the voltage V_{SRC} is greater than the threshold voltage of the memory cell MC regardless of the data stored in the memory cell MC. Therefore, an electron channel is formed in the channel region of the non-selected memory cell MC, and the voltage V_{SRC} is transferred to the write memory cell MC.

In the write operation, a program voltage V_{PGM} is supplied to the selected word line WL_{S}. The program voltage V_{PGM} is greater than the write pass voltage V_{PASS}.

Here, the voltage V_{SRC} is supplied to the channel of the semiconductor pillar 120 connected to the bit line BL_{W}. A relatively large electric field is generated between such semiconductor pillar 120 and the selected word line WL_{S}. Accordingly, electrons in the channel of the semiconductor pillar 120 tunnel into the charge storage film of the gate insulating film 130 (FIG. 5). Therefore, the threshold voltage of the write memory cell MC increases.

Meanwhile, the channel of the semiconductor pillar 120 connected to the bit line BL_{P} enters an electrically floating state, and potential of the channel rises to approximately the write pass voltage V_{PASS} due to capacitive coupling with the non-selected word lines WL_{U}. Between such semiconductor pillar 120 and the selected word line WL_{S}, an electric field smaller than the electric field described above occurs. Therefore, electrons in the channel of the semiconductor pillar 120 do not tunnel into the charge storage film of the gate insulating film 130 (FIG. 5). Therefore, the threshold voltage of the inhibited memory cell MC does not increase.

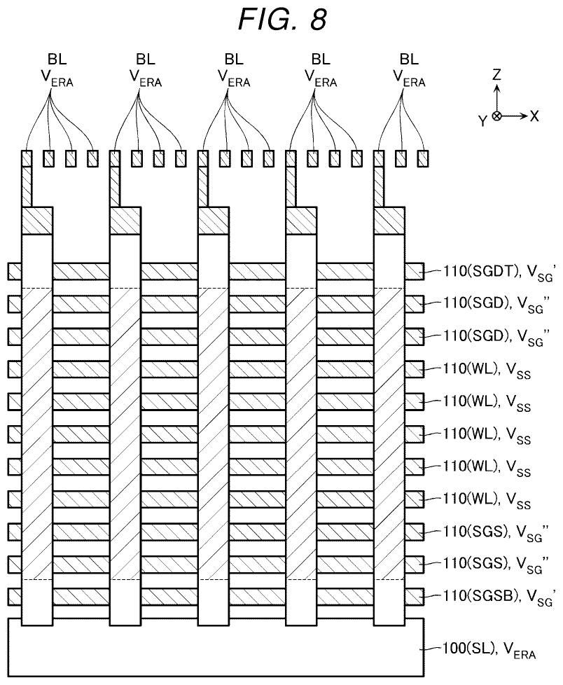

FIG. 8 is a schematic cross-sectional view illustrating the erase operation.

In the erase operation, an erase voltage V_{ERA} is supplied to the bit line BL and the source line SL. The erase voltage V_{ERA} may be, for example, greater than the program voltage V_{PGM} or may be equal to the program voltage V_{PGM}.

In the erase operation, a voltage V_{SG}′ is supplied to the drain-side select gate line SGDT. The voltage V_{SG}′ is less than the erase voltage V_{ERA}. Accordingly, a gate induced drain leakage (GIDL) occurs in the drain-side select transistor STDT, thereby generating electron-hole pairs. The electrons move to the bit line BL side, and the holes move to the memory cell MC side.

In the erase operation, a voltage V_{SG}″ is supplied to the drain-side select gate line SGD. The voltage V_{SG}″ is smaller than the erase voltage V_{ERA} and greater than the voltage V_{SG}′. Thus, a hole channel is formed in the channel region of the drain-side select transistor STD, and the holes are transferred to the memory cell MC side.

In the erase operation, the voltage V_{SG}′ is supplied to the source-side select gate line SGSB. Thus, GIDL occurs in the source-side select transistor STSB, thereby generating electron-hole pairs. The electrons move to the source line SL side, and the holes move to the memory cell MC side.

In the erase operation, the voltage V_{SG}″ is supplied to the source-side select gate line SGS. Thus, a hole channel is formed in the channel region of the source-side select transistor STS, and the holes are transferred to the memory cell MC side.

In the erase operation, the ground voltage V_{SS} is supplied to the word line WL. Accordingly, holes in the channel of the semiconductor pillar 120 tunnel into the charge storage film of the gate insulating film 130 (FIG. 5). Therefore, the threshold voltage of the memory cell MC decreases.

### Configuration of Peripheral Circuit PC

FIG. 9 is a schematic block diagram illustrating a configuration of the peripheral circuit PC.

FIG. 9 illustrates a plurality of control terminals and the like. The plurality of control terminals may be represented as control terminals corresponding to a high active signal (positive logic signal), represented as control terminals corresponding to a low active signal (negative logic signal), or represented as control terminals corresponding to both a high active signal and a low active signal. In FIG. 9, a symbol for the control terminal corresponding to the high active signal includes an overline. In the present specification, a symbol for the control terminal corresponding to the low active signal includes a slash (“/”). It should be noted that the illustration of FIG. 9 is merely an example, and specific aspects may be appropriately adjusted. For example, it is possible to change a portion or all of the high active signals to the low active signals, or to change a portion or all of the low active signals to the high active signals.

Arrows indicating input/output directions are illustrated beside the plurality of control terminals illustrated in FIG. 9. In FIG. 9, a control terminal with an arrow going from left to right can be used to input data or other signals from the controller die CD to the memory die MD. In FIG. 9, a control terminal with an arrow going from right to left can be used to output data or other signals from the memory die MD to the controller die CD. In FIG. 9, a control terminal with a double-headed arrow can be used both for inputting data or other signals from the controller die CD to the memory die MD and for outputting data or other signals from the memory die MD to the controller die CD.

The peripheral circuit PC includes a row decoder RD and the sense amplifier SA connected to the memory cell array MCA, and a cache memory CM connected to the sense amplifier SA. The peripheral circuit PC includes a voltage generating circuit VG and a sequencer SQC (which is a control circuit). The peripheral circuit PC includes an input/output control circuit I/O, a logic circuit CTR, an address register ADR, a command register CMR, a status register STR, and a temperature register TMPR. The peripheral circuit PC includes a temperature sensor TMPS.

The row decoder RD includes, for example, a block decoder that decodes a block address in a row address RA included in address data Add, and a voltage transfer circuit that electrically connects the plurality of word lines WL (FIG. 4) provided in one of a plurality of memory blocks BLK to a plurality of voltage supply lines (not illustrated) according to an output signal from the block decoder.

The sense amplifier SA includes a plurality of sense circuits and a plurality of voltage transfer circuits connected to the plurality of bit lines BL, and a data latch circuit. For example, in the read operation, the sense circuit latches data of “0” or “1” based on the voltage or the current of the bit line BL in a data latch circuit according to a control signal from the sequencer SQC. In the write operation, for example, the voltage transfer circuit adjusts the voltage of the bit line BL to “H” or “L” based on the data of “0” or “1” latched in the data latch circuit according to the control signal from the sequencer SQC. The user data Dat in the data latch circuit is output to the input/output control circuit I/O via the cache memory CM and a data bus DB. User data Dat input from the input/output control circuit I/O is stored in the data latch circuit in the sense amplifier SA via the data bus DB and the cache memory CM.

The voltage generating circuit VG includes, for example, a voltage step-up circuit such as a charge pump circuit and a voltage step-down circuit such as a regulator. The voltage step-up circuit and the voltage step-down circuit are each connected to voltage supply lines to which a power supply voltage V_{CC} and the ground voltage V_{SS} are supplied. The voltage supply lines are connected to, for example, the pad electrode P described with reference to FIGS. 2 and 3. For example, the voltage generating circuit VG generates a plurality of operating voltages to be applied to the bit lines BL, the source lines SL, the word lines WL and the select gate lines SGD and SGS in the read operation, the write operation and the erase operation for the memory cell array MCA according to the control signal from the sequencer SQC, and supplies the generated operating voltages to the bit lines BL, the source lines SL, the word lines WL and the select gate lines SGDT, SGD, SGS, and SGSB via the plurality of voltage supply lines. The operating voltage output from the voltage supply line is appropriately adjusted according to the control signal from the sequencer SQC.

The sequencer SQC outputs internal control signals to the row decoder RD, the sense amplifier SA, and the voltage generating circuit VG according to command data Cmd input to the command register CMR. The sequencer SQC appropriately outputs status data Stt indicating a state of the memory die MD to the status register STR.

The sequencer SQC generates a ready/busy signal and outputs the ready/busy signal to a terminal RY//BY. The terminal RY//BY enters an “L” state while executing an operation of supplying a voltage to the memory cell array MCA, such as the read operation, the write operation, or the erase operation, and enters a “H” state otherwise. In a period when the terminal RY//BY is in an “L” state (busy period), access to the memory die MD is basically prohibited. In a period when the terminal RY//BY is in a “H” state (ready period), access to the memory die MD is permitted. The terminal RY//BY is implemented by, for example, the pad electrode P described with reference to FIGS. 2 and 3.

The address register ADR is connected to the input/output control circuit I/O, and stores the address data Add input from the input/output control circuit I/O. The address register ADR includes, for example, a plurality of 8-bit register strings. When an internal operation such as the read operation, the write operation, or the erase operation is executed, the register string stores the address data Add corresponding to the internal operation being executed.

The address data Add includes, for example, a column address CA and the row address RA. The row address RA includes, for example, a block address that specifies the memory block BLK (FIG. 4), a page address that specifies the string unit SU and the word line WL, a plane address that specifies the memory cell array MCA, and a chip address that specifies the memory die MD.

The command register CMR is connected to the input/output control circuit I/O, and the command data Cmd is input from the input/output control circuit I/O. When command data Cmd is input to the command register CMR, a control signal is sent to the sequencer SQC.

The status register STR is connected to the input/output control circuit I/O, and stores the status data Stt to be output to the input/output control circuit I/O. The status register STR includes, for example, a plurality of 8-bit register strings. When an internal operation such as the read operation, the write operation, or the erase operation is executed, the register string stores the status data Stt related to the internal operation being executed. The register string stores, for example, ready/busy information on the memory cell array MCA.

The temperature register TMPR is connected to the temperature sensor TMPS and the sequencer SQC, and stores temperature data Tmp read from the temperature sensor TMPS. The temperature register TMPR includes, for example, at least one 8-bit register string.

The input/output control circuit I/O includes data signal input/output terminals DQ0 to DQ7, data strobe signal input/output terminals DQS and/DQS, a plurality of input circuits and driver circuits connected to each of the data signal input/output terminals DQ0 to DQ7, and a shift register connected to the plurality of input circuits and output circuits. The input circuit is, for example, an input receiver such as a comparator. The driver circuit functions as an off chip driver (OCD) circuit that outputs data and adjusts an output impedance in data output, for example. The driver circuit also functions as a circuit that adjusts an input impedance in data input. In the following description, the driver circuit is referred to as a termination resistance adjusting circuit.

Each of the data signal input/output terminals DQ0 to DQ7 and the data strobe signal input/output terminals DQS and/DQS is implemented by, for example, the pad electrode P described with reference to FIGS. 2 and 3. Data input via the data signal input/output terminals DQ0 to DQ7 is input to the cache memory CM, the address register ADR, or the command register CMR according to the internal control signal from the logic circuit CTR. Data output via the data signal input/output terminals DQ0 to DQ7 is output from the cache memory CM or the status register STR according to the internal control signal from the logic circuit CTR.

The signals input via the data strobe signal input/output terminals DQS and/DQS (for example, a data strobe signal and a complementary signal thereof) are used to input data via the data signal input/output terminals DQ0 to DQ7. Data input via the data signal input/output terminals DQ0 to DQ7 is taken into the shift register in the input/output control circuit I/O at timings of a rising edge of voltage at the data strobe signal input/output terminal DQS and a falling edge of voltage at the data strobe signal input/output terminal/DQS as well as a falling edge of voltage at the data strobe signal input/output terminal DQS and a rising edge of voltage at the data strobe signal input/output terminal/DQS.

The logic circuit CTR includes a plurality of external control terminals/CE, CLE, ALE, /WE, /RE and RE, and logic circuits connected to the plurality of external control terminals/CE, CLE, ALE, /WE, /RE and RE. The logic circuit CTR receives external control signals from the controller die CD via the external control terminals/CE, CLE, ALE, /WE, /RE, and RE, and outputs internal control signals to the input/output control circuit I/O in response thereto.

Each of the external control terminals/CE, CLE, ALE, /WE, /RE, and RE is implemented by, for example, the pad electrode P described with reference to FIGS. 2 and 3.

A signal input via the external control terminal/CE (for example, a chip enable signal) is used to select the memory die MD. The memory die MD in which “L” is input to the external control terminal/CE enters a state in which input and output of the user data Dat, the command data Cmd, and the address data Add (hereinafter sometimes simply referred to as “data”) is enabled. The memory die MD in which “H” is input to the external control terminal/CE enters a state in which data input and output is disabled.

A signal input via the external control terminal CLE (for example, a command latch enable signal) is used in connection with the use of the command register CMR. When “H” is input to the external control terminal CLE, data input via the data signal input/output terminals DQ0 to DQ7 is stored as the command data Cmd in a buffer memory in the input/output control circuit I/O and transferred to the command register CMR.

A signal input via the external control terminal ALE (for example, an address latch enable signal) is used in connection with the use of the address register ADR. When “H” is input to the external control terminal ALE, data input via the data signal input/output terminals DQ0 to DQ7 is stored as the address data Add in the buffer memory in the input/output control circuit I/O and transferred to the address register ADR.

When “L” is input to both of the external control terminals CLE and ALE, data input via the data signal input/output terminals DQ0 to DQ7 is stored as the user data Dat in the shift register in the input/output control circuit I/O. The user data Dat stored in the shift register is transferred to the cache memory CM via the data bus DB.

A signal input via the external control terminal/WE (for example, a write enable signal) is used to input data via the data signal input/output terminals DQ0 to DQ7. Data input via the data signal input/output terminals DQ0 to DQ7 is taken into the shift register, the command register CMR or the address register ADR in the input/output control circuit I/O at a timing of a rising edge of voltage (switching of input signal) at the external control terminal/WE.

In data input, the external control terminal/WE may be used, or the data strobe signal input/output terminals DQS and/DQS may be used.

Signals input via the external control terminals/RE and RE (for example, a read enable signal and a complementary signal thereof) are used to output data via the data signal input/output terminals DQ0 to DQ7. Data input via the data signal input/output terminals DQ0 to DQ7 is switched at a timing of a rising edge of voltage at the external control terminal RE and a falling edge of voltage at the external control terminal/RE, as well as a falling edge of voltage at the external control terminal RE and a rising edge of voltage at the external control terminal/RE.

### Configuration of Termination Resistance Adjusting Circuit in Input/Output Control Circuit I/O

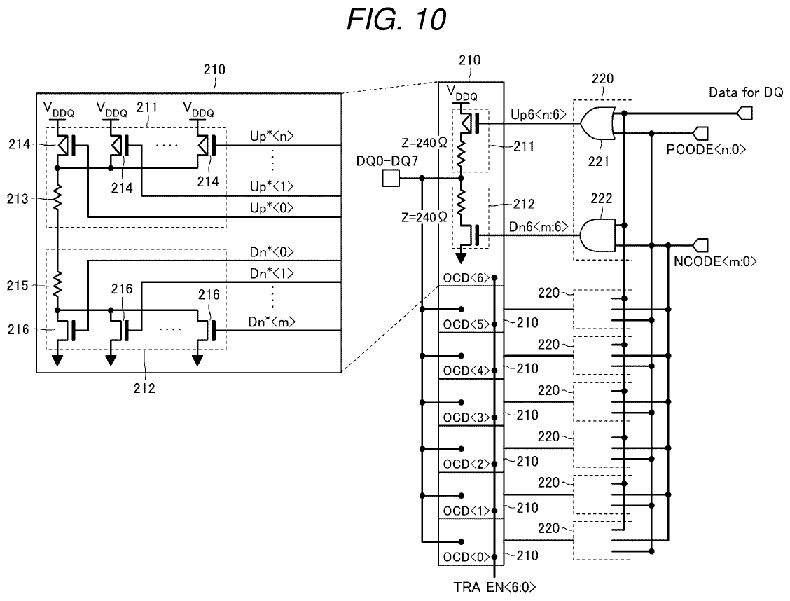

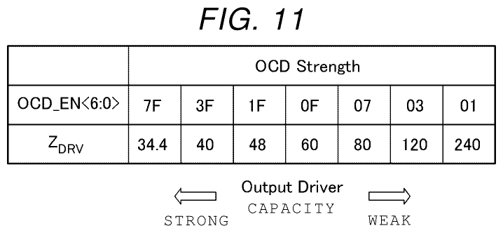

FIG. 10 is a schematic circuit diagram illustrating a configuration of the termination resistance adjusting circuit in the input/output control circuit I/O. FIG. 11 is a table illustrating impedances of the termination resistance adjusting circuit.

The termination resistance adjusting circuit includes seven termination resistance adjustment units 210 connected in parallel to the data signal input/output terminals DQ0 to DQ7 and the data strobe signal input/output terminals DQS and/DQS, and seven termination resistance adjustment unit control circuits 220 connected to the seven termination resistance adjustment units 210.

Each of the seven termination resistance adjustment units 210 has an impedance of 240 Ω. The seven termination resistance adjustment units 210 are each connected to a signal line TRA_EN<6:0>, and the number of termination resistance adjustment units 210 to be driven is controlled according to the signal line TRA_EN<6:0>. For example, when a signal 0000001 (01 in hexadecimal) is input to the signal line TRA_EN<6:0>, an impedance Z_{DRV} of the termination resistance adjusting circuit is set to approximately 240 Ω, as illustrated in FIG. 11. For example, when a signal 0011111 (1F in hexadecimal) is input to the signal line TRA_EN<6:0>, the impedance Z_{DRV} of the termination resistance adjusting circuit is set to approximately 240 Ω/5=48 Ω. A signal of the signal line TRA_EN<6:0> is controlled, for example, by a user.

Each of the termination resistance adjustment units 210 includes a pull-up circuit 211 connected between a voltage supply line to which a voltage V_{DDQ} is supplied and the data signal input/output terminals DQ0 to DQ7 and the data strobe signal input/output terminals DQS and/DQS, for example, as illustrated in FIG. 10. Each of the termination resistance adjustment units 210 includes a pull-down circuit 212 connected between the data signal input/output terminals DQ0 to DQ7 and the data strobe signal input/output terminals DQS and/DQS and the pad electrode P to which the ground voltage V_{SS} is supplied.

The pull-up circuit 211 includes a resistance element 213 connected to the data signal input/output terminals DQ0 to DQ7 or the data strobe signal input/output terminals DQS and/DQS, and n+1 (n is a natural number) transistors 214 connected in parallel between the resistance element 213 and the voltage supply line to which the voltage V_{DDQ} is supplied. The transistor 214 is a PMOS transistor. The n+1 transistors 214 each have at least one of a different channel width and a different channel length, and have n+1 different resistance values. Gate electrodes of the n+1 transistors 214 are connected to signal lines Up*<0> to Up*<n> (* is any of 0 to 6), respectively. The (n+1)-bit data input to the signal lines Up*<0> to Up*<n> is adjusted such that an impedance of the pull-up circuit 211 during driving is approximately 240 Ω.

The pull-down circuit 212 includes a resistance element 215 connected to the data signal input/output terminals DQ0 to DQ7 or the data strobe signal input/output terminals DQS and/DQS, and m+1 (m is a natural number) transistors 216 connected in parallel between the resistance element 215 and the pad electrode P to which the ground voltage V_{SS} is supplied. The transistor 216 is an NMOS transistor. The m+1 transistors 216 each have at least one of a different channel width and a different channel length, and have m+1 different resistance values. Gate electrodes of the m+1 transistors 216 are connected to signal lines Dn*<0> to Dn*<m> (* is any of 0 to 6), respectively. Then, the (m+1)-bit data input to the signal lines Dn*<0> to Dn*<m> is adjusted such that an impedance of the pull-down circuit 212 during driving is approximately 240 Ω.

The termination resistance adjustment unit control circuit 220 includes, for example, n+1 OR circuits 221 and m+1 AND circuits 222.

In data output, a signal of “1” or “0” output from the data signal input/output terminals DQ0 to DQ7, or a clock signal output from the data strobe signal input/output terminals DQS and/DQS is input to one input terminal of each of the n+1 OR circuits 221. The other input terminal of each of the n+1 OR circuits 221 receives corresponding bits of (n+1)-bit data PCODE<n:0> corresponding to the n+1 PMOS transistors in the pull-up circuit 211.

In data output, a signal of “1” or “0” output from the data signal input/output terminals DQ0 to DQ7, or a clock signal output from the data strobe signal input/output terminals DQS and/DQS is input to one input terminal of each of the m+1 AND circuits 222. The other input terminal of each of the m+1 AND circuits 222 receives corresponding bits of (m+1)-bit data NCODE<m:0> corresponding to the m+1 NMOS transistors in the pull-down circuit 212.

In data input, the signals of the one input terminal of each of the n+1 OR circuits 221 and the one input terminal of each of the m+1 AND circuits 222 are fixed to “1” or “0”. Corresponding bits of the (n+1)-bit data PCODE<n:0> and corresponding bits of the (m+1)-bit data NCODE<m:0> are input to the signals of the other input terminal of each of the n+1 OR circuits 221 and the other input terminal of each of the m+1 AND circuits 222.

The data PCODE<n:0> used in data input may be different from the data PCODE<n:0> used in data output. Similarly, the data NCODE<m:0> used in data input may be different from the data NCODE<m:0> used in data output.

### Configuration of Calibration Circuit

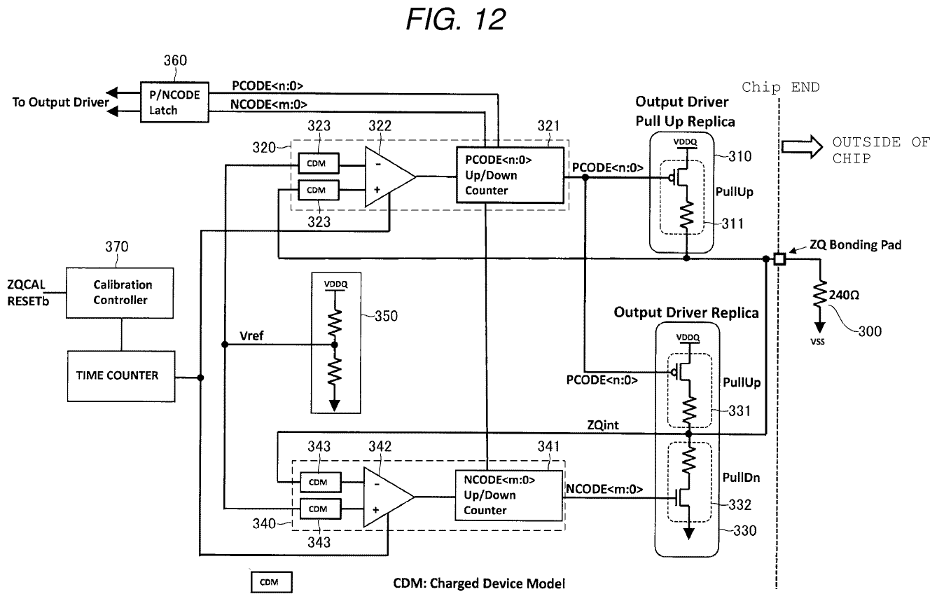

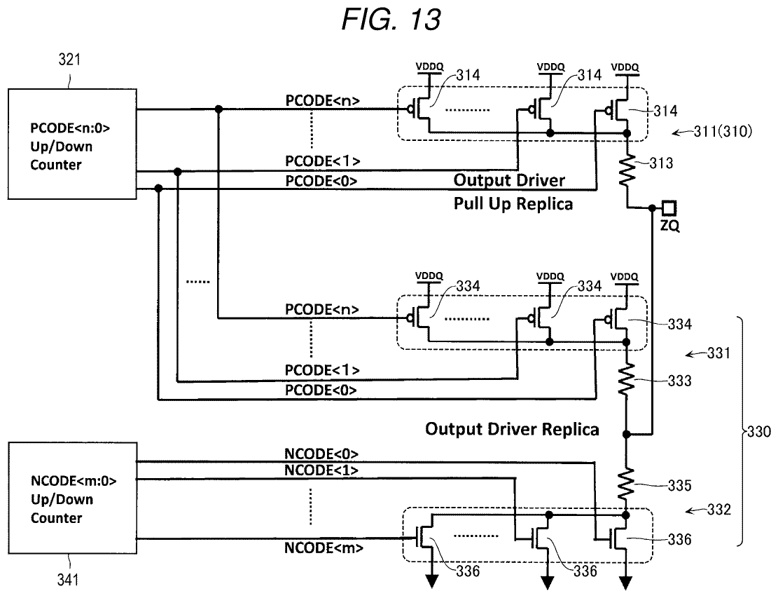

FIGS. 12 and 13 are schematic circuit diagrams illustrating a configuration of a calibration circuit.

Although not illustrated in FIG. 9, the peripheral circuit PC includes the calibration circuit. The calibration circuit adjusts the data PCODE<n:0> and the data NCODE<m:0> such that impedances of the pull-up circuit 211 and the pull-down circuit 212 during driving are approximately 240 Ω.

As illustrated in FIG. 12, the calibration circuit includes a first replica unit 310 connected to a calibration electrode ZQ, a first replica unit control circuit 320 connected to the first replica unit 310, a second replica unit 330 connected to the calibration electrode ZQ, a second replica unit control circuit 340 connected to the second replica unit 330, a reference voltage generating circuit 350, a data latch circuit 360, and a calibration control circuit 370.

The first replica unit 310 includes a pull-up circuit 311 connected between the voltage supply line to which the voltage V_{DDQ} is supplied and the calibration electrode ZQ.

As illustrated in FIG. 13, the pull-up circuit 311 includes a resistance element 313 connected to the calibration electrode ZQ, and n+1 transistors 314 connected in parallel between the resistance element 313 and the voltage supply line to which the voltage V_{DDQ} is supplied. The transistor 314 is a PMOS transistor. The n+1 transistors 314 each have at least one of a different channel width and a different channel length, and have n+1 different resistance values. Gate electrodes of the n+1 transistors 314 are connected to the n+1 signal lines, respectively. The data PCODE<n:0> is input to the n+1 signal lines.

As illustrated in FIG. 12, the first replica unit control circuit 320 includes a counter 321 that outputs the data PCODE<n:0>, a comparator 322 that controls the counter 321, and an ESD protection circuit 323 connected to an input terminal of the comparator 322.

The counter 321 adjusts the data PCODE<n:0> in synchronization with the clock signal. For example, when an output signal of the comparator 322 is in an “L” state, “1” is subtracted from a value indicated by the (n+1)-bit data PCODE<n:0>. When the output signal of the comparator 322 is in a “H” state, the counter 321 adds “1” to the value indicated by the (n+1)-bit data PCODE<n:0>.

An inverting input terminal of the comparator 322 is connected to the reference voltage generating circuit 350 via the ESD protection circuit 323. A non-inverting input terminal of the comparator 322 is connected to the calibration electrode ZQ via the ESD protection circuit 323. The comparator 322 is controlled by the calibration control circuit 370.

The ESD protection circuit 323 protects the comparator 322 from sudden charging and discharging caused by static electricity or the like.

The second replica unit 330 includes a pull-up circuit 331 connected between the voltage supply line to which the voltage V_{DDQ} is supplied and the calibration electrode ZQ. The second replica unit 330 also includes a pull-down circuit 332 connected between the calibration electrode ZQ and an electrode that supplies the ground voltage V_{SS}.

As illustrated in FIG. 13, the pull-up circuit 331 includes a resistance element 333 connected to the calibration electrode ZQ, and n+1 transistors 334 connected in parallel between the resistance element 333 and the voltage supply line to which the voltage V_{DDQ} is supplied. The transistor 334 is a PMOS transistor. The n+1 transistors 334 each have at least one of a different channel width and a different channel length, and have n+1 different resistance values. Gate electrodes of the n+1 transistors 334 are connected to the n+1 signal lines, respectively. The data PCODE<n:0> is input to the n+1 signal lines.

As illustrated in FIG. 13, the pull-down circuit 332 includes a resistance element 335 connected to the calibration electrode ZQ, and m+1 transistors 336 connected in parallel between the resistance element 335 and the electrode that supplies the ground voltage V_{SS}. The transistor 336 is an NMOS transistor. The m+1 transistors 336 each have at least one of a different channel width and a different channel length, and have m+1 different resistance values. Gate electrodes of the m+1 transistors 336 are connected to the m+1 signal lines, respectively. The data NCODE<m:0> is input to the m+1 signal lines.

As illustrated in FIG. 12, the second replica unit control circuit 340 includes a counter 341 that outputs the data NCODE<m:0>, a comparator 342 that controls the counter 341, and an ESD protection circuit 343 connected to an input terminal of the comparator 342.

The counter 341 adjusts the data NCODE<m:0> in synchronization with the clock signal. For example, when an output signal of the comparator 342 is in an “L” state, “1” is added to a value indicated by the (m+1)-bit data NCODE<m:0>. When the output signal of the comparator 342 is in a “H” state, the counter 341 subtracts “1” from the value indicated by the (m+1)-bit data NCODE<m:0>.

An inverting input terminal of the comparator 342 is connected to the reference voltage generating circuit 350 via the ESD protection circuit 343. A non-inverting input terminal of the comparator 342 is connected to the calibration electrode ZQ via the ESD protection circuit 343. The comparator 342 is controlled by the calibration control circuit 370.

The ESD protection circuit 343 protects the comparator 342 from sudden charging and discharging caused by static electricity or the like.

The reference voltage generating circuit 350 includes, for example, a voltage dividing circuit. The voltage dividing circuit includes two resistance elements connected in series between the voltage supply line to which the voltage V_{DDQ} is supplied and the electrode to which the ground voltage V_{SS} is supplied, and an output terminal connected between the two resistance elements. The two resistance elements have the same resistance value, and a voltage of an output terminal becomes half the voltage of the voltage supply line to which the voltage V_{DDQ} is supplied.

The data latch circuit 360 stores the data PCODE<n:0> output from the first replica unit control circuit 320 and the data NCODE<m:0> output from the second replica unit control circuit 340, and outputs the stored data to the termination resistance adjusting circuit.

The calibration control circuit 370 controls the first replica unit control circuit 320 and the second replica unit control circuit 340. For example, the first replica unit control circuit 320 is controlled to adjust the data PCODE<n:0>, and next, the second replica unit control circuit 340 is controlled to adjust the data NCODE<m:0>.

### Operation of Calibration Circuit

In the calibration operation of the semiconductor device according to the present embodiment, the first replica unit control circuit 320 is controlled to adjust the data PCODE<n:0>. Here, the calibration electrode ZQ is connected to the voltage supply line to which the voltage V_{DDQ} is supplied via the pull-up circuit 311, and is connected to the electrode that supplies the ground voltage V_{SS} from outside the semiconductor device via a series resistor 300 having a resistance value of approximately 240 Ω. When the first replica unit control circuit 320 is controlled, the data PCODE<n:0> is adjusted such that a voltage of a calibration electrode ZQm of a memory die MD0 becomes approximately a reference voltage (½ V_{DDQ}). Accordingly, the data PCODE<n:0> is adjusted such that an impedance of the pull-up circuit 311 during driving is approximately 240 Ω. Then, the data latch circuit 360 stores the data PCODE<n:0> output from the first replica unit control circuit 320.

Next, the second replica unit control circuit 340 is controlled to adjust the data NCODE<m:0> . Here, the calibration electrode ZQ is connected to the voltage supply line to which the voltage V_{DDQ} is supplied via the pull-up circuit 331, and is connected to the electrode that supplies the ground voltage V_{SS} via the pull-down circuit 332. An impedance of the pull-up circuit 331 is adjusted to approximately 240 Ω. When the second replica unit control circuit 340 is controlled, the data NCODE<m:0> is adjusted such that a voltage of the calibration electrode ZQ becomes approximately the reference voltage (½ V_{DDQ}). Accordingly, the data NCODE<m:0> is adjusted such that an impedance of the pull-down circuit 332 during driving is approximately 240 Ω. Then, the data latch circuit 360 stores the data NCODE<m:0> output from the second replica unit control circuit 340.

### Acquisition of Two Types of Data PCODE<n:0> and NCODE<m:0>

The calibration circuit may include two sets of the first replica unit 310 and the first replica unit control circuit 320 to adjust both the data PCODE<n:0> used in data output and the data PCODE<n:0> used in data input. Similarly, the calibration circuit may include two sets of the second replica unit 330 and the second replica unit control circuit 340 to adjust both the data NCODE<m:0> used in data output and the data NCODE<m:0> used in data input.

For example, the data PCODE<n:0> and NCODE<m:0> used in data input may be the same as the data PCODE<n:0> and NCODE<m:0> used in data output, or may be calculated based on the data PCODE<n:0> and NCODE<m:0> used in data output.

### Timing of Executing Calibration Operation

The impedances of the pull-up circuit 211 and the pull-down circuit 212 in the termination resistance adjusting circuit vary in response to changes in a power supply voltage, a temperature, and the like. Therefore, it is preferable to execute the calibration operation appropriately in response to changes in operating conditions.

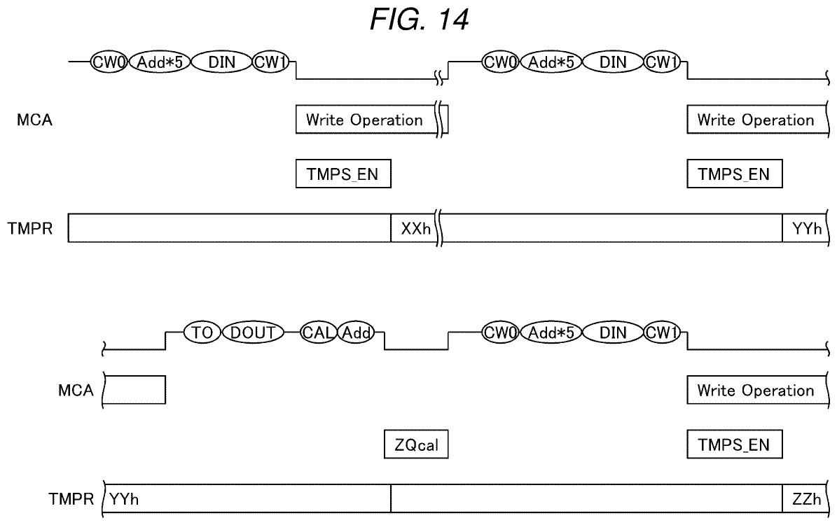

FIG. 14 is a schematic timing chart illustrating a timing of executing the calibration operation. In FIG. 14, a period during which the temperature sensor TMPS is driven is indicated as “TMPS_EN”. A period during which the calibration operation is being executed is indicated as “ZQcal”.

In the illustrated example, first, the controller die CD (FIG. 1) inputs a first command set instructing the write operation to the memory die MD. The command set includes data CW0, Add, DIN, and CW1.

The controller die CD (FIG. 1) inputs the data CW0 as command data Cmd to the memory die MD. That is, the external control terminal/WE is raised from “L” to “H” while the voltages of the data signal input/output terminals DQ0 to DQ7 are set to “H” or “L” according to each bit of the data CW0, “H” is input to the external control terminal CLE, and “L” is input to the external control terminal ALE. The data CW0 is a command input when starting the write operation.

Next, the controller die CD inputs the address data Add to the memory die MD. That is, the external control terminal/WE is raised from “L” to “H” while the voltages of the data signal input/output terminals DQ0 to DQ7 are set to “H” or “L” according to each bit of the address data Add, “L” is input to the external control terminal CLE, and “H” is input to the external control terminal ALE. The address data Add is input by five cycles.

Next, the controller die CD inputs the data DIN as the user data Dat to the memory die MD. That is, the signals of the data strobe signal input/output terminals DQS and/DQS are switched while the voltages of the data signal input/output terminals DQ0 to DQ7 are set to “H” or “L” according to each bit of the data DIN, “L” is input to the external control terminal CLE, and “L” is input to the external control terminal ALE. The data DIN is input by a plurality of cycles.

Next, the controller die CD inputs the data CW1 as the command data Cmd to the memory die MD. The data CW1 is a command indicating that input of the command set instructing the write operation has completed.

When the first command set has been input, the memory die MD enters a busy state, and the terminal RY//BY changes from a “H” state to an “L” state. Accordingly, access to the memory die MD is prohibited. The write operation is started in the memory die MD, and the data DIN in the command set is written into the memory cell array MCA.

In the illustrated example, the temperature sensor TMPS is driven when the write operation starts, and data XXh is obtained as the temperature data Tmp. The data XXh is stored as the temperature data Tmp in the temperature register TMPR.

When the write operation has completed, the memory die MD enters a ready state, and the terminal RY//BY changes from an “L” state to a “H” state. Accordingly, access to the memory die MD is permitted. In the illustrated example, here, a second command set instructing the write operation is input. The second command set is basically the same as the first command set, but contents of the data Add and DIN are different.

When the second command set has been input, the memory die MD enters a busy state, and the terminal RY//BY changes from a “H” state to an “L” state. Accordingly, access to the memory die MD is prohibited. The write operation is started in the memory die MD, and the data DIN in the command set is written into the memory cell array MCA.

In the illustrated example, the temperature sensor TMPS is driven when the write operation starts, and data YYh is obtained as the temperature data Tmp. The data YYh is stored as the temperature data Tmp in the temperature register TMPR.

When the write operation has completed, the memory die MD enters a ready state, and the terminal RY//BY changes from an “L” state to a “H” state. Accordingly, access to the memory die MD is permitted.

Here, in the illustrated example, the controller die CD inputs data TO to the memory die MD as the command data Cmd. The data TO is a command for instructing output of the temperature data Tmp stored in the temperature register TMPR. Thus, the voltages of the data signal input/output terminals DQ0 to DQ7 are set to “H” or “L” according to each bit of the temperature data Tmp.

Next, the controller die CD acquires the temperature data Tmp. Here, for example, when the data YYh indicates a temperature equal to or higher than a predetermined temperature, the controller die CD inputs a command set instructing the calibration operation to the memory die MD. The command set includes the data CAL and Add.

That is, the controller die CD inputs the data CAL as the command data Cmd to the memory die MD. The data CAL is a command input when starting the calibration operation.

Next, the controller die CD inputs the address data Add to the memory die MD. Th address data Add includes, for example, a chip address for specifying the memory die MD to execute the calibration operation.

When the command set instructing the calibration operation has been input, the memory die MD enters a busy state, and the terminal RY//BY changes from a “H” state to an “L” state. Accordingly, access to the memory die MD is prohibited. The calibration operation is started in the memory die MD.

When the calibration operation has completed, the memory die MD enters a ready state, and the terminal RY//BY changes from an “L” state to a “H” state. Accordingly, access to the memory die MD is permitted. In the illustrated example, here, a third command set instructing the write operation is input. The third command set is basically the same as the first command set, but contents of the data Add and DIN are different.

Here, a temperature of the memory die MD may fluctuate due to execution of the core operation such as the write operation. When the temperature of the memory die MD fluctuates, the impedances of the pull-up circuit 211 and the pull-down circuit 212 in the termination resistance adjusting circuit also fluctuate. Therefore, for example, when the write operation is executed continuously as in FIG. 14, it is preferable to execute the calibration operation when executing the second and subsequent write operations.

Here, in the example of FIG. 14, after the second write operation is executed, the terminal RY//BY changes from an “L” state to a “H” state, and then the controller die CD acquires the temperature data Tmp in the memory die MD. Whether the calibration operation is necessary is determined based on the temperature data Tmp, and when it is determined that the calibration operation is necessary, the command set instructing the memory die MD to perform the calibration operation is input. After the calibration operation has completed, the next write operation is started.

### Calibration Operation During Core Operation

The semiconductor device of the present embodiment is capable of acquiring the temperature data Tmp during execution of the core operation, determining whether execution of the calibration operation is necessary based on the acquired temperature data Tmp, and executing the calibration operation depending on a determination result.

According to the configuration, it is possible to adjust the impedances of the pull-up circuit 211 and the pull-down circuit 212 in the termination resistance adjusting circuit in a period from the start to the end of the core operation. Therefore, when continuously executing the write operation, there is no need to acquire the temperature data Tmp and execute the calibration operation between the first write operation and the second write operation. Therefore, it is possible to provide, for example, a semiconductor device that operates at a higher speed than the example described with reference to FIG. 14.

### Calibration Operation During Write Operation

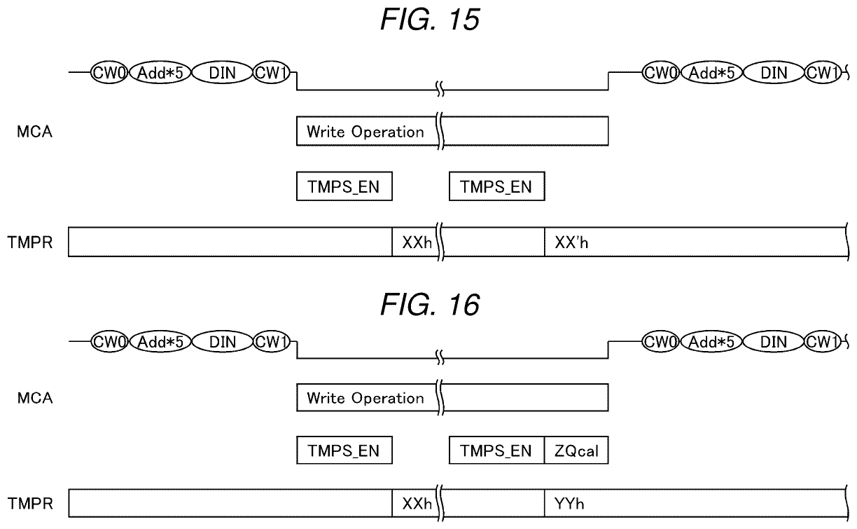

FIGS. 15 and 16 are schematic timing charts illustrating the calibration operation during the write operation. In FIGS. 15 and 16, the period during which the temperature sensor TMPS is driven is indicated as “TMPS_EN”. The period during which the calibration operation is being executed is indicated as “ZQcal”.

In the example of FIG. 15, first, the controller die CD (FIG. 1) inputs the first command set instructing the write operation to the memory die MD.

When the first command set has been input, the memory die MD enters a busy state, and the terminal RY//BY changes from a “H” state to an “L” state. Accordingly, access to the memory die MD is prohibited. The write operation is started in the memory die MD.

In the illustrated example, the temperature sensor TMPS is driven when the write operation starts, and the data XXh is obtained as the temperature data Tmp. The data XXh is stored as the temperature data Tmp in the temperature register TMPR.

Here, in the example of FIG. 15, at a predetermined stage of the write operation, the temperature sensor TMPS is driven again, and data XX′h is acquired as the temperature data Tmp. The data XX′h is stored as the temperature data Tmp in the temperature register TMPR. The data XX′h is data indicating a temperature approximately equal to that of the data XXh. Here, the calibration operation is not executed during execution of the write operation.

Meanwhile, in the example of FIG. 16, at a predetermined stage of the write operation, the temperature sensor TMPS is driven again, and data YYh is acquired as the temperature data Tmp. The data YYh is stored as the temperature data Tmp in the temperature register TMPR. The data YYh is data indicating a temperature different from the data XXh by a predetermined amount or more. Here, the calibration operation is executed during execution of the write operation. In the example of FIG. 16, execution of the calibration operation is completed at a timing when execution of the write operation has completed.

The condition as to whether to execute the calibration operation during the write operation can be set appropriately. For example, a plurality of temperature ranges with a plurality of threshold values as boundaries may be set in advance, and when the data XXh stored in the temperature register TMPR and the temperature data Tmp acquired from the temperature sensor TMPS are in the same temperature range, the calibration operation may not be executed, and when the data XXh and the temperature data Tmp are in different temperature ranges, the calibration operation may be executed.

The plurality of threshold values as the boundaries of the plurality of temperature ranges may be stored as feature data in a register inside the memory die MD. Here, the plurality of threshold values may be values rewritable by the set feature. The plurality of threshold values may be stored as ROM parameters in a ROM region in the memory cell array MCA. Even then, the plurality of threshold values may be rewritable.

When the write operation has completed, the memory die MD enters a ready state, and the terminal RY//BY changes from an “L” state to a “H” state. Accordingly, access to the memory die MD is permitted. In the illustrated example, here, the second command set instructing the write operation is input.

According to the method, when the first write operation has completed, the input impedances of the pull-up circuit 211 and the pull-down circuit 212 in the termination resistance adjusting circuit are appropriately adjusted. Therefore, even when the temperature of the memory die MD fluctuates, the user data Dat included in the second command set can be appropriately input to the memory die MD.

In the method, whether the calibration operation is necessary is determined according to the temperature data Tmp. Therefore, when the calibration operation is not necessary, it is possible to omit execution of the calibration operation. Accordingly, it is possible to reduce power consumption.

### Calibration Operation During Read Operation

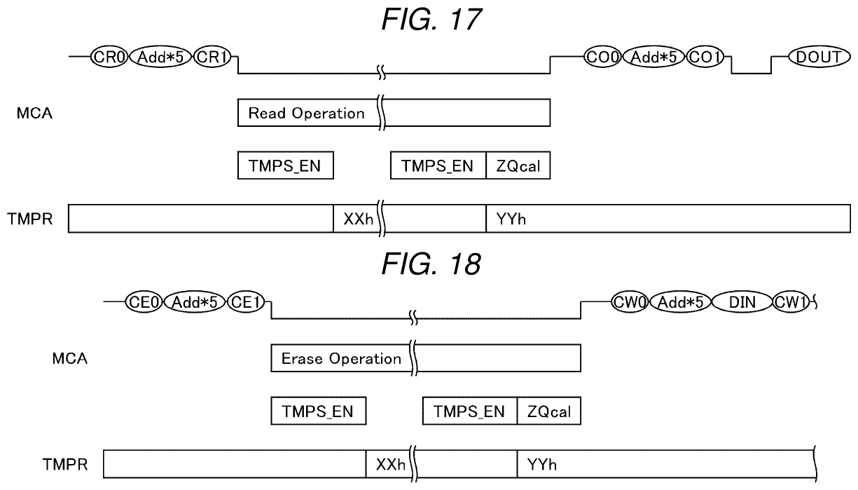

FIG. 17 is a schematic timing chart illustrating the calibration operation during the read operation. In FIG. 17, the period during which the temperature sensor TMPS is driven is indicated as “TMPS_EN”. The period during which the calibration operation is being executed is indicated as “ZQcal”.

In the example of FIG. 17, first, the controller die CD (FIG. 1) inputs a command set instructing the read operation to the memory die MD. The command set includes the data CR0, Add, and CR1.

That is, the controller die CD (FIG. 1) inputs the data CR0 as the command data Cmd to the memory die MD. The data CR0 is a command input when the read operation starts.

Next, the controller die CD inputs the address data Add to the memory die MD.

Next, the controller die CD inputs the data CR1 as the command data Cmd to the memory die MD. The data CR1 is a command indicating that input of the command set instructing the read operation has completed.

When the command set instructing the read operation has been input, the memory die MD enters a busy state, and the terminal RY//BY changes from a “H” state to an “L” state. Accordingly, access to the memory die MD is prohibited. The read operation is started in the memory die MD, and the user data Dat read from the memory cell array MCA is stored in the cache memory CM.

In the illustrated example, the temperature sensor TMPS is driven when the read operation starts, and the data XXh is obtained as the temperature data Tmp. The data XXh is stored as the temperature data Tmp in the temperature register TMPR.

Here, in the example of FIG. 17, at a predetermined stage of the read operation, the temperature sensor TMPS is driven again, and data YYh is acquired as the temperature data Tmp. The data YYh is stored as the temperature data Tmp in the temperature register TMPR. The data YYh is data indicating a temperature different from the data XXh by a predetermined amount or more. Here, the calibration operation is executed during execution of the read operation. In the example of FIG. 17, execution of the calibration operation is completed at a timing when execution of the read operation has completed.

Although not illustrated, when the temperature data Tmp acquired at a predetermined stage of the read operation indicates a temperature approximately equal to that of the data XXh, the calibration operation is not executed during execution of the read operation.

The condition as to whether to execute the calibration operation during the read operation can be set similarly to the condition as to whether to execute the calibration operation during the write operation.

When the read operation has completed, the memory die MD enters a ready state, and the terminal RY//BY changes from an “L” state to a “H” state. Accordingly, access to the memory die MD is permitted. In the illustrated example, here, a command set instructing a data out operation is input. The command set includes the data CO0, Add, and CO1.

That is, the controller die CD (FIG. 1) inputs the data CO0 as the command data Cmd to the memory die MD. The data CO0 is a command input when the data out operation starts.

Next, the controller die CD inputs the address data Add to the memory die MD.

Next, the controller die CD inputs the data CO1 as the command data Cmd to the memory die MD. The data CO1 is a command indicating that input of the command set instructing the data out operation has completed.

When the command set instructing the data out operation has been input, the memory die MD enters a busy state, and the terminal RY//BY changes from a “H” state to an “L” state. Accordingly, access to the memory die MD is prohibited. The user data Dat stored in the cache memory CM becomes a state in which the user data Dat can be output via the input/output control circuit I/O.

After a predetermined time elapses, the memory die MD enters a ready state, and the terminal RY//BY changes from an “L” state to a “H” state. Accordingly, access to the memory die MD is permitted. In the illustrated example, here, the controller die CD acquires data DOUT as the user data Dat from the memory die MD.

That is, here, 8-bit data in the data DOUT is output via the data signal input/output terminals DQ0 to DQ7. Specifically, the voltages of the data signal input/output terminals DQ0 to DQ7 are set to “H” or “L” according to the 8-bit data included in the data DOUT. When the controller die CD switches the signals of the external control terminals/RE and RE, the next 8-bit data in the data DOUT is output via the data signal input/output terminals DQ0 to DQ7. The controller die CD acquires the signals output from the data signal input/output terminals DQ0 to DQ7 while switching the signals of the external control terminals/RE and RE. The data DOUT is output by a plurality of cycles.

According to the method, when the read operation has completed, the output impedances of the pull-up circuit 211 and the pull-down circuit 212 in the termination resistance adjusting circuit are appropriately adjusted. Therefore, even when the temperature of the memory die MD fluctuates, the user data Dat stored in the cache memory CM can be appropriately output to the controller die CD.

In the method, whether the calibration operation is necessary is determined according to the temperature data Tmp. Therefore, when the calibration operation is not necessary, it is possible to omit execution of the calibration operation. Accordingly, it is possible to reduce power consumption.

### Calibration Operation During Erase Operation

FIG. 18 is a schematic timing chart illustrating the calibration operation during the erase operation. In FIG. 18, the period during which the temperature sensor TMPS is driven is indicated as “TMPS_EN”. The period during which the calibration operation is being executed is indicated as “ZQcal”.

In the example of FIG. 18, first, the controller die CD (FIG. 1) inputs a command set instructing the erase operation to the memory die MD. The command set includes the data CE0, Add, and CE1.

That is, the controller die CD (FIG. 1) inputs the data CE0 as the command data Cmd to the memory die MD. The data CE0 is a command input when the erase operation starts.

Next, the controller die CD inputs the address data Add to the memory die MD.

Next, the controller die CD inputs the data CE1 as the command data Cmd to the memory die MD. The data CE1 is a command indicating that input of the command set instructing the erase operation has completed.

When the command set instructing the erase operation has been input, the memory die MD enters a busy state, and the terminal RY//BY changes from a “H” state to an “L” state. Accordingly, access to the memory die MD is prohibited. The erase operation is started in the memory die MD, and the user data Dat in the memory block BLK designated by the address data Add is erased.

In the illustrated example, the temperature sensor TMPS is driven when the erase operation starts, and the data XXh is obtained as the temperature data Tmp. The data XXh is stored as the temperature data Tmp in the temperature register TMPR.

Here, in the example of FIG. 18, at a predetermined stage of the erase operation, the temperature sensor TMPS is driven again, and data YYh is acquired as the temperature data Tmp. The data YYh is stored as the temperature data Tmp in the temperature register TMPR. The data YYh is data indicating a temperature different from the data XXh by a predetermined amount or more. Here, the calibration operation is executed during execution of the erase operation. In the example of FIG. 18, execution of the calibration operation is completed at a timing when execution of the erase operation has completed.

Although not illustrated, when the temperature data Tmp acquired at a predetermined stage of the erase operation indicates a temperature approximately equal to that of the data XXh, the calibration operation is not executed during execution of the erase operation.

The condition as to whether to execute the calibration operation during the erase operation can be set similarly to the condition as to whether to execute the calibration operation during the write operation.

When the erase operation has completed, the memory die MD enters a ready state, and the terminal RY//BY changes from an “L” state to a “H” state. Accordingly, access to the memory die MD is permitted. In the illustrated example, here, the command set instructing the write operation is input.

According to the method, when the erase operation has completed, the input impedances of the pull-up circuit 211 and the pull-down circuit 212 in the termination resistance adjusting circuit are appropriately adjusted. Therefore, even when the temperature of the memory die MD fluctuates, the user data Dat included in the command set instructing the write operation can be appropriately input to the memory die MD.

In the method, whether the calibration operation is necessary is determined according to the temperature data Tmp. Therefore, when the calibration operation is not necessary, it is possible to omit execution of the calibration operation. Accordingly, it is possible to reduce power consumption.

### Calibration Operation During Recovery Operation

A time required for the write operation is longer than that of the read operation. A time required for the erase operation is even longer than the time required for the write operation. Therefore, when it is necessary to execute the read operation during execution of the write operation or the erase operation, the write operation or the erase operation may be paused, the read operation may be executed, and the write operation or the erase operation may be resumed after the read operation is executed. Similarly, the erase operation may be paused, the write operation may be executed, and the erase operation may be resumed after the write operation is executed.

Here, when the write operation or the erase operation is paused, the memory die MD executes an operation to return the memory die MD to a state in which the read operation, the write operation, or the like can be executed, for example, by discharging electric charges from the bit lines BL and the word lines WL, or by adjusting a state of the voltage generating circuit VG. Hereinafter, such operation will be referred to as a recovery operation. In the present embodiment, it is possible to execute the calibration operation even during execution of the recovery operation.

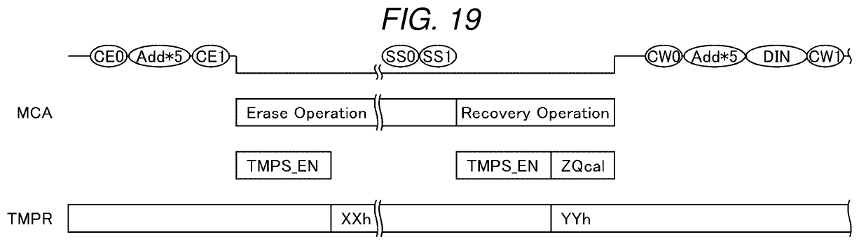

FIG. 19 is a schematic timing chart illustrating the calibration operation during the recovery operation. FIG. 19 illustrates an example in which the erase operation is paused and the write operation is executed. In FIG. 19, the period during which the temperature sensor TMPS is driven is indicated as “TMPS_EN”. The period during which the calibration operation is being executed is indicated as “ZQcal”.

In the example of FIG. 19, during execution of the erase operation, the controller die CD (FIG. 1) inputs a command set for pausing the core operation to the memory die MD. The command set includes data SS0 and SS1.

That is, the controller die CD (FIG. 1) sequentially inputs the data SS0 and SS1 as the command data Cmd to the memory die MD. The data SS0 and SS1 are commands input when the core operation is paused.

When the command set for pausing the core operation has been input, the recovery operation is started in the memory die MD.

In the illustrated example, the temperature sensor TMPS is driven when the recovery operation starts, and data YYh is acquired as the temperature data Tmp. The data YYh is stored as the temperature data Tmp in the temperature register TMPR. The data YYh is data indicating a temperature different from the data XXh by a predetermined amount or more. Here, the calibration operation is executed during execution of the recovery operation. In the example of FIG. 19, execution of the calibration operation is completed at a timing when execution of the recovery operation has completed.

Although not illustrated, when the temperature data Tmp acquired during the recovery operation indicates a temperature approximately equal to that of the data XXh, the calibration operation is not executed during execution of the recovery operation.

The condition as to whether to execute the calibration operation during the recovery operation can be set similarly to the condition as to whether to execute the calibration operation during the write operation.

When the recovery operation has completed, the memory die MD enters a ready state, and the terminal RY//BY changes from an “L” state to a “H” state. Accordingly, access to the memory die MD is permitted. In the illustrated example, here, the command set instructing the write operation is input.

According to the method, when the recovery operation has completed, the input impedances of the pull-up circuit 211 and the pull-down circuit 212 in the termination resistance adjusting circuit are appropriately adjusted. Therefore, even when the temperature of the memory die MD fluctuates, the user data Dat included in the command set instructing the write operation can be appropriately input to the memory die MD.

In the method, whether the calibration operation is necessary is determined according to the temperature data Tmp. Therefore, when the calibration operation is not necessary, it is possible to omit execution of the calibration operation. Accordingly, it is possible to reduce power consumption.

### Second Embodiment

In the first embodiment, the temperature sensor TMPS in the memory die MD is driven during execution of the core operation, and the temperature sensor TMPS is used to determine whether the calibration operation is necessary. However, the configuration is merely an example, and specific operations or the like can be adjusted as appropriate. In the second embodiment, an example in which a temperature sensor outside the memory die MD is used will be described.

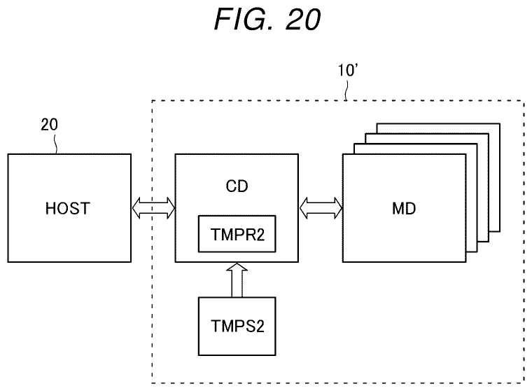

FIG. 20 is a schematic block diagram illustrating a configuration of a memory system 10′ according to the second embodiment.

The memory system 10′ is basically configured similarly to the memory system 10 according to the first embodiment. However, the memory system 10′ includes a temperature sensor TMPS2 connected to the controller die CD in addition to the plurality of memory dies MD and the controller die CD. The controller die CD according to the present embodiment includes a temperature register TMPR2.

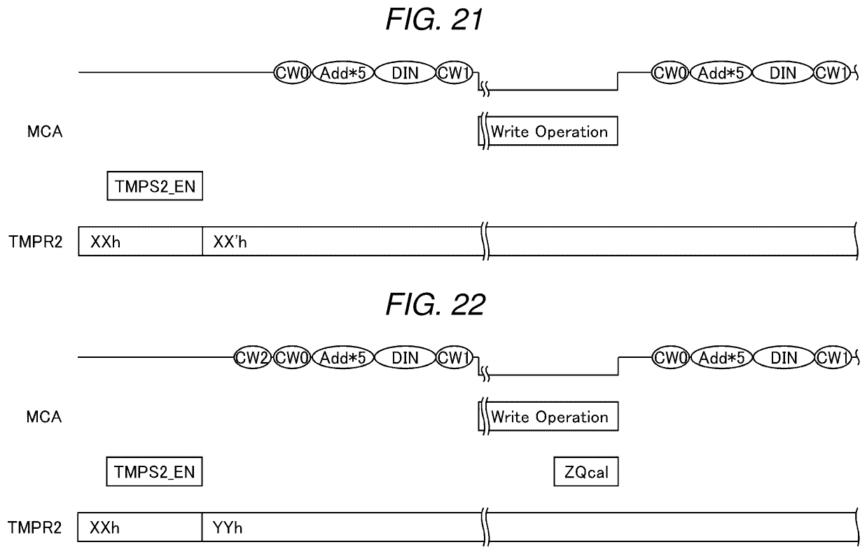

FIGS. 21 and 22 are schematic timing charts illustrating the calibration operation during the write operation. In FIGS. 21 and 22, a period during which the temperature sensor TMPS2 is driven is indicated as “TMPS2_EN”. The period during which the calibration operation is being executed is indicated as “ZQcal”.

In the example of FIG. 21, first, the temperature sensor TMPS2 is driven, and data XX′h is acquired as the temperature data Tmp. The data XX′h is stored as the temperature data Tmp in the temperature register TMPR2. The data XX′h indicates a temperature approximately equal to that of data XXh originally stored in the temperature register TMPR2. Here, the controller die CD inputs a normal command set instructing the write operation to the memory die MD. In response, the write operation is executed in the memory die MD. However, the calibration operation is not executed during execution of the write operation.

Meanwhile, in the example of FIG. 22, the temperature sensor TMPS2 is driven, and data YYh is acquired as the temperature data Tmp. The data YYh is stored as the temperature data Tmp in the temperature register TMPR2. The data YYh is data indicating a temperature different from the data XXh by a predetermined amount or more. Here, the controller die CD inputs a command set instructing the write operation and instructing the calibration operation during the write operation to the memory die MD. In the illustrated example, the command set includes data CW2, CW0, Add, DIN, and CW1. In response, the write operation is executed in the memory die MD. The calibration operation is executed during execution of the write operation.

The condition as to whether to execute the calibration operation during the write operation can be set appropriately as in the first embodiment.

In the second embodiment, a plurality of threshold values as boundaries of a plurality of temperature ranges may be stored in a register (not illustrated) in the controller die CD. As in the first embodiment, the plurality of threshold values may be rewritable.

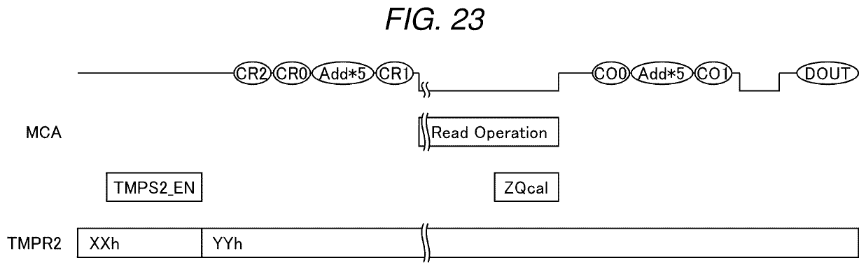

FIG. 23 is a schematic timing chart illustrating the calibration operation during the read operation. In FIG. 23, the period during which the temperature sensor TMPS2 is driven is indicated as “TMPS2_EN”. The period during which the calibration operation is being executed is indicated as “ZQcal”.

In the example of FIG. 23, first, the temperature sensor TMPS2 is driven, and data YYh is acquired as the temperature data Tmp. The data YYh is stored as the temperature data Tmp in the temperature register TMPR2. The data YYh is data indicating a temperature different from the data XXh by a predetermined amount or more. Here, the controller die CD inputs a command set instructing the read operation and instructing the calibration operation during the read operation to the memory die MD. In response, the read operation is executed in the memory die MD. The calibration operation is executed during execution of the read operation.

Although not illustrated in the drawings, when the acquired temperature data Tmp indicates a temperature approximately equal to that of the data XXh, the controller die CD inputs a normal command set instructing the read operation to the memory die MD. Here, the calibration operation is not executed in the memory die MD during execution of the read operation.

The condition as to whether to execute the calibration operation during the read operation can be set appropriately as in the first embodiment.

Although not illustrated in the drawings, in the present embodiment, when executing the erase operation, similarly to the write operation and the read operation, the temperature data Tmp is obtained from the temperature sensor TMPS2, whether the calibration operation is necessary is determined based on the temperature data Tmp, and it is possible to input a normal command set instructing the erase operation or a command set instructing the erase operation and instructing the calibration operation during the erase operation to the memory die MD depending on a determination result.

Similarly, in the present embodiment, when executing the recovery operation after pausing the write operation or the erase operation, as in the write operation and the read operation, the temperature data Tmp is obtained from the temperature sensor TMPS2, whether the calibration operation is necessary is determined based on the temperature data Tmp, and it is possible to input a normal command set pausing the core operation or a command set pausing the core operation and instructing the calibration operation during the next recovery operation to the memory die MD depending on a determination result.

### Other Embodiments

The semiconductor devices according to the first embodiment and the second embodiment were described above. However, the configurations are merely examples, and specific configurations or the like can be changed as appropriate. For example, in the first embodiment and the second embodiment, communication between the memory die MD and the controller die CD may conform to a single data rate (SDR) interface, a toggle double data rate (DDR) interface, or an open NAND flash interface (ONFI).

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
an electrode used in data input and output;
a pull-up circuit and a pull-down circuit, each configured to control a voltage of the electrode;
an internal circuit configured to output data via the electrode and to receive data via the electrode;
a control circuit capable of executing an internal operation of the internal circuit and a calibration operation of adjusting impedances of the pull-up circuit and the pull-down circuit; and
a temperature sensor configured to supply temperature data to the control circuit, wherein
the control circuit is configured to acquire the temperature data from the temperature sensor during execution of the internal operation, and execute the calibration operation according to the acquired temperature data.

2. The semiconductor device according to claim 1, further comprising:
a register for storing reference temperature data, wherein
during execution of the internal operation, the control circuit
acquires the temperature data from the temperature sensor, and compares the acquired temperature data to the reference temperature data, and
executes the calibration operation based on a result of comparing the acquired temperature data to the reference temperature data.

3. The semiconductor device according to claim 2, wherein the control circuit does not execute the calibration operation when the acquired temperature data and the reference temperature data are in the same temperature range, and executes the calibration operation when the acquired temperature data and the reference temperature data are in temperature ranges different from each other.

4. The semiconductor device according to claim 3, wherein
boundary values of the temperature ranges are rewritable values.

5. The semiconductor device according to claim 1, wherein
the internal circuit includes a memory cell, and
the internal operation of the internal circuit is a read operation, a write operation, or an erase operation performed on the memory cell.

6. The semiconductor device according to claim 1, wherein
the internal circuit includes a memory cell, and
the control circuit is configured to execute
a write operation and an erase operation on the memory cell, and a recovery operation after pausing the write operation or the erase operation, and
the internal operation of the internal circuit is the recovery operation.

7. The semiconductor device according to claim 1, wherein
the internal circuit further includes a memory string that includes a plurality of memory cell transistors connected in series.

8. The semiconductor device according to claim 1, wherein communication with the controller complies with open NAND flash interface (ONFI).

9. A data processing system comprising:
a semiconductor device;
a control device configured to control the semiconductor device; and
a temperature sensor configured to supply temperature data to the control device, wherein:
the semiconductor device includes
an electrode used in data input from the control device and data output to the control device,
a pull-up circuit and a pull-down circuit, each configured to control a voltage of the electrode,
an internal circuit configured to output data via the electrode and to receive data via the electrode, and
a control circuit capable of executing an internal operation of the internal circuit and a calibration operation of adjusting impedances of the pull-up circuit and the pull-down circuit;
the control device acquires the temperature data from the temperature sensor during execution of the internal operation, and inputs a first command set or a second command set to the semiconductor device according to the acquired temperature data; and
the semiconductor device executes the calibration operation during execution of the internal operation when the first command set is input, and does not execute the calibration operation during execution of the internal operation when the second command set is input.

10. The data processing system according to claim 9, wherein
the control device includes a register that stores a reference temperature data,
during execution of the internal operation, the control device acquires the temperature data from the temperature sensor,
inputs the second command set to the semiconductor device when the reference temperature data and the acquired temperature data are in the same temperature range, and
inputs the first command set to the semiconductor device when the reference temperature data and the acquired temperature data are in temperature ranges different from each other.

11. The data processing system according to claim 10, wherein boundary values of the temperature ranges are rewritable values.

12. The data processing system according to claim 9, wherein
the internal circuit includes a memory cell, and
the internal operation of the internal circuit is a read operation, a write operation, or an erase operation performed on the memory cell.

13. The data processing system according to claim 9, wherein
the internal circuit includes a memory cell,
the control circuit is configured to execute
a write operation and an erase operation on the memory cell, and a recovery operation after pausing the write operation or the erase operation, and
the internal operation of the internal circuit is the recovery operation.

14. The data processing system according to claim 9, wherein
the internal circuit further includes a memory string that includes a plurality of memory cell transistors connected in series.

15. The data processing system according to claim 9, wherein communication with the controller complies with open NAND flash interface (ONFI).

16. A method of performing an internal operation on a memory cell of a semiconductor device having an electrode used in data input and output, a pull-up circuit and a pull-down circuit, each configured to control a voltage of the electrode, an internal circuit configured to output data via the electrode and to receive data via the electrode, and a temperature sensor, said method comprising:
acquiring temperature data measured by the temperature sensor while the internal operation is being executed;
comparing the acquired temperature data with a reference temperature data; and
executing a calibration operation of adjusting impedances of the pull-up circuit and the pull-down circuit based on a result of comparing the acquired temperature data with a reference temperature data.

17. The method according to claim 16, wherein the calibration operation is not executed when the acquired temperature data and the reference temperature data are in the same temperature range, and is executed when the acquired temperature data and the reference temperature data are in temperature ranges different from each other.

18. The method according to claim 17, further comprising:
resetting the temperature ranges.

19. The method according to claim 17, wherein the internal operation includes a read operation, a write operation, and an erase operation.

20. The method according to claim 19, wherein the internal operation includes a recovery operation that is executed after the write operation or the erase operation is paused.
